(19) United States
(12) Patent Application Publication
(10) Pub. No.: US 2015/0306570 A1
(43) Pub. Date: Oct. 29, 2015

(54) METAL-CARBON COMPOSITES AND METHODS FOR THEIR PRODUCTION

(71) Applicant: UT-Battelle, LLC, Oak Ridge, TN (US)

(72) Inventors: Richard T. Mayes, Knoxville, TN (US); James O. Kiggans, Jr., Oak Ridge, TN (US); Sheng Dai, Knoxville, TN (US); David William DePaoli, Knoxville, TN (US); Constantinos Tsouris, Oak Ridge, TN (US); William H. Peter, Knoxville, TN (US)

(21) Appl. No.: 14/264,121

(22) Filed: Apr. 29, 2014

(51) Int. Cl. B01J 21/18; C09D 5/24; H05K 9/00; H01B 13/00; H01F 1/01; C09D 5/10; A01N 59/00; H01M 4/36; C02F 1/46

(52) U.S. Cl. CPC B01J 21/18; H01M 4/364; C09D 5/24; H05K 9/0092; C02F 1/4604; H01F 1/01; C09D 5/10; A01N 59/00; H01B 13/0026

(57) ABSTRACT

A method of forming a metal-carbon composite, the method comprising subjecting a precursor composition to a curing step followed by a carbonization step, the precursor composition comprising: (i) a phenolic component, (ii) a crosslinkable aldehyde component, (iii) a polymerization catalyst, and (iv) metal-containing particles, wherein said carbonization step comprises heating the precursor composition at a carbonizing temperature of at least 300° C. for sufficient time to convert the precursor composition to said metal-carbon composite. The produced metal-carbon composite, devices incorporating them, and methods of their use (e.g., in capacitive deionization and lithium ion batteries) are also described.

This invention was made with government support under Prime Contract No. DE-AC05-00OR22725 awarded by the U.S. Department of Energy. The government has certain rights in the invention.

### FIELD OF THE INVENTION

The present invention relates to the field of metal-carbon composite materials and methods for producing coatings and monolithic structures thereof.

### BACKGROUND OF THE INVENTION

Metal-carbon composites can have a variety of utilities, including as catalysts, electrode and battery materials, sensors, anti-corrosive materials, anti-microbial materials, capacitive materials, energy storage materials, conductive agents, electromagnetic interference (EMI) shielding materials, gas separation materials, water purification materials, and magnetic materials. However, current methods for the production of metal-carbon composites are substantially limited, particularly in the production of films and coatings thereof.

In particular, while it is known in the art to produce metal-carbon materials by combining metal and carbon particles and treating them by powder metallurgical techniques (e.g., blending, molding, and sintering), such methods are generally not useful in producing films and coatings of such composites. Moreover, where coatings of metal-carbon composites are produced in the art, complex and expensive methodology is generally employed, such as magnetron sputtering, chemical vapor deposition (CVD), and plasma enhanced chemical vapor deposition (PECVD). Thus, there would be a significant benefit in a facile, cost-effective, and generally applicable method for producing a wide range of metal-carbon composites, and particularly films and coatings thereof.

### SUMMARY OF THE INVENTION

The instant disclosure is particularly directed to a facile and generally applicable method for producing a metal-carbon composite. The method disclosed herein is particularly useful for producing films and coatings of metal-carbon composites on a range of substrates.

More particularly, the method includes subjecting a precursor composition to a curing step followed by a carbonization step, the precursor composition containing at least: (i) a phenolic component, (ii) a crosslinkable aldehyde component, (iii) a polymerization catalyst, and (iv) metal-containing particles. The carbonization step generally involves heating the precursor composition at a carbonizing temperature of at least 300° C. for sufficient time to convert the precursor composition to the metal-carbon composite. Generally, the metal is an element selected from Groups 3-12 (i.e., a transition metal), lanthanide, and actinide metals of the Periodic Table. In specific embodiments, the metal is a transition metal selected from Groups 3-12 of the Periodic Table. The carbon component, as derived from the cured phenol-aldehyde resin, generally functions as a matrix in which the metal particles are embedded or dispersed. In particular, the carbon matrix generally maintains the shape and structural integrity of the composite, and optionally conductivity, while the metal provides a further property of interest, such as catalytic activity or magnetism. Thus, a costly or rare metal may advantageously be incorporated in minute amounts, as dispersed in the carbon matrix, while the resultant composite possesses similar or improved properties compared to the unadulterated metal. In some embodiments, the activity of the metal may be enhanced by dispersal of the metal-containing particles in the carbon matrix, or by a synergistic interaction between the metal and carbon matrix.

In particular embodiments, the precursor composition is in the form of a liquid and is deposited onto a substrate in liquid form by any suitable technique (e.g., spraying, dipping, or spin-coating), followed by curing and carbonization of the produced coating. The coating method is particularly advantageous by producing metal-carbon composite coatings on substrates having any degree of structural intricacy and providing them with new or additional properties not found in the substrate. The described coating process is further advantageous by circumventing the need to produce an entire object from the metal-carbon composite, as in a molding process. Moreover, once cured or carbonized, the coating may be removed to form a monolithic film or other shape.

### DETAILED DESCRIPTION OF THE INVENTION

In one aspect, the invention is directed to a metal-carbon composite. The term “metal-carbon composite”, as used herein, refers to a solid material having at least an elemental carbon matrix (i.e., “carbon matrix”) and metal-containing particles incorporated therein. In some embodiments, the metal-carbon composite contains only these two components. The metal-containing particles are, at least to some extent, dispersed or embedded within the carbon matrix, wherein the carbon matrix is non-particulate (i.e., not constructed of fused or bonded carbon particles), and may or may not include pores whose walls are constructed of carbon. Since the carbon matrix is not constructed of fused carbon particles, the surface of the instant metal-carbon composite is advantageously smooth and of generally uniform thickness. Moreover, as interfacial points of attachment between fused or bound carbon particles are highly prone to mechanical failure on application of physical stress, the non-particulate carbon matrix employed herein is substantially less prone to such failure.

The metal-containing particles can have any suitable size. In one set of embodiments, the metal-containing particles are nanoparticles. The nanoparticles have a size in one, two, or all of their dimensions of less than 1 micron, and more typically, a size up to or less than 500 nm, 250 nm, or 100 nm. In different embodiments, the metal-containing nanoparticles have a uniform or average size of precisely, about, up to, or less than, for example, 1 nm, 2 nm, 5 nm, 10 nm, 20 nm, 30 nm, 40 nm, 50 nm, 100 nm, 150 nm, 200 nm, 300 nm, 400 nm, 500 nm, 600 nm, 700 nm, 800 nm, or 900 nm, or a size within a range bounded by any two of the foregoing values, or between any of the foregoing values and less than 1 micron. In another set of embodiments, the metal-containing particles are microparticles or microparticles, which may correspond to a uniform or average size (in one, two, or all of their dimensions) of precisely, about, up to, less than, at least, or above, for example, 1 μm, 2 μm, 5 μm, 10 μm, 20 μm, 50 μm, 100 μm, or 200 μm. In another set of embodiments, the metal-containing particles are microparticles, which may correspond to a uniform or average size (in one, two, or all of their dimensions) of precisely, about, up to, less than, at least, or above, for example, 500 μm, 1000 μm, 2000 μm, 3000 μm, 4000 μm, or 5000 μm. In another set of embodiments, the metal-containing particles have a size within a range that overlaps any of the nanoparticle, microparticle, or microparticle sizes provided above. Moreover, any of the exemplary particle sizes provided above may refer to primary or secondary (agglomerated) particle sizes. The metal-containing particles may also be porous or non-porous.

As used herein, the term “about” generally indicates within ±0.5%, 1%, 2%, 5%, or up to 10% of the indicated value. For example, a particle size of “about 10 nm” generally indicates, in its broadest sense, 10 nm±10%, which indicates 9.0-11.0 nm. In addition, the term “about” can indicate either a measurement error (i.e., by limitations in the measurement method), or alternatively, a variation or average in a physical characteristic of a group (e.g., a population of particle sizes).

The metal-containing particles can also have any of a variety of shapes. In a first embodiment, the metal-containing particles are substantially spherical or ovoid. In a second embodiment, the metal-containing particles are substantially elongated, and may be rod-shaped, tubular, or even fibrous. In a third embodiment, the metal-containing particles are plate-like, with one dimension significantly smaller than the other two. In a fourth, the metal-containing particles have a substantially polyhedral shape, such as a pyramidal, cuboidal, rectangular, or prismatic shape. In a fifth embodiment, the metal-containing particles are substantially amorphous.

The metal-containing particles have a composition that includes metal atoms of any valency and selected from one or more of any of Groups 3-14 of the Periodic Table of the Elements (i.e., the Periodic Table), lanthanide elements, and actinide elements. In a first set of embodiments, the metal is selected from one or more elements of Groups 3-12 of the Periodic Table, wherein elements of Groups 3-12 are generally referred to as transition metals. The transition metal can be selected from, for example, Group 3 (Sc or Y), Group 4 (Ti, Zr, or Hf), Group 5 (V, Nb, or Ta), Group 6 (Cr, Mo, or W), Group 7 (Mn, Tc, or Re), Group 8 (Fe, Ru, or Os), Group 9 (Co, Rh, or Ir), Group 10 (Ni, Pd, or Pt), Group 11 (Cu, Ag, or Au), or Group 12 (Zn, Cd, or Hg). As is well known in the art, the transition metals may also be categorized by row, i.e., first row (starting with Sc), second row (starting with Y), or third row transition metals (starting with Hf). In a second set of embodiments, the metal is selected from one or more elements of Group 13 (i.e., B, Al, Ga, or In) and/or Group 14 (i.e., Si, Ge, Sn, or Pb) of the Periodic Table, wherein these elements are generally referred to as main group metals. For purposes of the invention, the Group 14 metal does not include carbon. In a third set of embodiments, the metal is selected from one or more lanthanide elements, which are any of the elements having an atomic number selected from 57 to 71 (e.g., La, Ce, Pr, Nd, Eu, Gd, Tb, and the like). In a fourth set of embodiments, the metal is selected from one or more actinide elements, which are any of the elements having an atomic number of 90-103 (e.g., Th, U, Pu, Am, and the like). Moreover, when two or more metals are included in the metal-containing particles, they may be selected from any of the different groupings of elements provided above, such as from transition and either main group, lanthanide, or actinide metal, or a ternary combination thereof; or from main group and either transition, lanthanide, or actinide metal, or a ternary combination thereof.

In some embodiments, the metal-containing particles have a zerovalent (i.e., elemental) composition. The zerovalent metal is typically a metal known to be substantially stable in the zerovalent state, with a resistance to oxidation or chemical reaction at elevated temperatures and under acidic or alkaline conditions. Some such zerovalent metals include, for example, cobalt (Co), rhodium (Rh), iridium (Ir), nickel (Ni), palladium (Pd), platinum (Pt), copper (Cu), silver (Ag), gold (Au), cadmium (Cd), aluminum (Al), and tin (Sn). The zerovalent metal particles may contain a single zerovalent metal, or may contain two or more zerovalent elements. In the case of two zerovalent metals, they may be present in the particle in a homogeneous manner (i.e., as an alloy), or in a heterogeneous manner, such as a core-shell arrangement. Particles of such elements are well known in the art.

In other embodiments, the metal-containing particles contain any of the metal atoms described above, but having a non-zero valency, in which case the metal-containing particles are composed of a metal-containing compound. The metal-containing compound contains the metal atoms in a non-zerovalent state in association with at least one element of opposite charge. The term “compound” also includes materials that may not fall within the strict sense of the term, e.g., polymeric, lattice, or non-stoichiometric compositions.

For example, in a first embodiment, the metal-containing particles have a metal oxide composition, such as a transition metal oxide, main group metal oxide, lanthanide metal oxide, or actinide metal oxide composition (wherein the oxide atoms function as the element of opposite charge to the metal atoms). Some examples of transition metal oxides include scandium oxide (e.g., Sc₂O₃, or scandia), yttrium oxide (e.g., Y₂O₃, or yttria), titanium oxides (e.g., TiO, TiO₂, and Ti₂O₃), zirconium oxides (e.g., ZrO₂, or zirconia), hafnium oxide (HfO₂), vanadium oxides (e.g., V₂O₅, VO, VO₂, V₂O₃, V₃O₇, V₄O₉, and V₆O₁₃), niobium oxides (e.g., NbO, NbO₂, and Nb₂O₅), tantalum oxides (e.g., Ta₂O₅), chromium oxides (e.g., Cr₂O₃ and CrO₂), molybdenum oxides (e.g., MoO₃ and MoO₂), tungsten oxides (e.g., W₂O₃, WO₂, and WO₃), manganese oxides (e.g., MnO, Mn₃O₄, Mn₂O₃, and MnO₂), rhenium oxides (e.g., ReO₂, ReO₃, and Re₂O₇), iron oxides (e.g., Fe₂O₃ and its different forms, FeO, and Fe₃O₄), ruthenium oxides (e.g., RuO₂), cobalt oxides (e.g., CoO and Co₃O₄), rhodium oxide, iridium oxide, nickel oxides (e.g., NiO), palladium oxide, platinum oxide, copper oxides (Cu₂O and CuO), silver oxide (Ag₂O), and zinc oxide (ZnO). Some examples of main group metal oxides include boron oxides (B₂O₃ and its different forms), aluminum oxides (e.g., Al₂O₃ and its different forms), gallium oxide (e.g., Ga₂O₃), indium oxide (e.g., In₂O₃), silicon oxide (e.g., SiO₂ and its different forms), germanium oxide (e.g., GeO₂ and GeO), tin oxide (e.g., SnO₂ and SnO), and lead oxides (e.g., PbO₂ and PbO). Some examples of lanthanide oxides include those based on the general formula (RE)O or (RE)O₂, such as CeO₂ (ceria). Some examples of actinide oxides include thorium oxide (e.g., ThO₂) and uranium oxides (e.g., UO₂, UO₃, or U₃O₈). The metal oxide composition may also include two or more metals, as in indium tin oxide (ITO), perovskite compositions (i.e., of the formula M′M″O₃, wherein M′ and M″ are independently monovalent, divalent, trivalent, tetravalent, or pentavalent metal ions, provided that the sum of oxidation states of M′ and M″ add to +6 to charge balance with oxide atoms), or spinel oxide compositions (i.e., of the formula M′M″₂O₄, wherein M′ and M″ are independently monovalent, divalent, trivalent, tetravalent, pentavalent, or hexavalent metal ions, provided that the sum of oxidation states of M′ and M″ add to +8 to charge balance with oxide atoms). In the case of two metal oxides, they may be present in the particle in a homogeneous manner (i.e., as a homogeneous mixture), or in a heterogeneous manner, such as a core-shell arrangement. Particles of such elements are well known in the art.

The metal-containing particles may alternatively be composed of any of the metals provided above and another element of Group 16, i.e., a metal sulfide, metal selenide, or metal telluride composition. Such compositions can correspond, for example, to any of the above metal oxide compositions wherein the oxide atoms therein are substituted with sulfide, selenide, or telluride atoms. Many of the metal sulfide, selenide, and telluride compositions are known in the art to be quantum dot compositions, which are commonly used in photovoltaics. Some examples of quantum dot compositions include CdS, CdSe, CdTe, CdSₓSe₁₋ₓ, ZnS, ZnSe, ZnTe, ZnSₓSe₁₋ₓ, Ga₂S₃, Ga₂Se₃, Ga₂Te₃, GaₓIn₂₋ₓSe₃, In₂S₃, In₂Se₃, In₂Te₃, CuS, CuSe, CuTe, PbS, PbSe, PbTe, CdₓZn₁₋ₓS, CdₓZn₁₋ₓSe, CdₓZn₁₋ₓTe, and CdₓZn₁₋ₓS_{y}Se_{1-y}, wherein x and y are, independently, an integral or non-integral numerical value greater than 0 and less than or equal to 1, or less than or equal to 2 for the expression 2-x.

The metal-containing compound may alternatively be composed of any of the metals provided above and an element of Group 15, e.g., a metal nitride, metal phosphide, metal arsenide, or metal antimonide. Some examples of metal nitride compositions include, for example, boron nitride (BN), aluminum nitride (AlN), gallium nitride (GaN), indium nitride (InN), indium gallium nitride (InGaN), vanadium nitride (e.g., VN), titanium nitride (e.g., TiN), yttrium nitride (e.g., YN), zirconium nitride (e.g., ZrN), and tungsten nitride (e.g., WN₂). Some examples of metal phosphide compositions include aluminum phosphide (AlP), gallium phosphide (GaP), and indium phosphide (InP). Some examples of metal arsenide compositions include Cd₃As₂, Zn₃As₂, GaAs, GaₓIn₁₋ₓAs, InAs, Cu₃As₂, and Pb₃As₂. Any of the foregoing compositions may also be regarded as a quantum dot composition. Particles of such compositions are well known in the art.

The metal-containing compound may alternatively be composed of any of the metals provided above and an element of Group 13 or 14, e.g., a metal carbide, metal silicide, or metal boride. Some examples of metal carbides include silicon carbide, aluminum carbide, vanadium carbide, iron carbide, titanium carbide, and uranium carbide. Some examples of metal silicides include iron silicide, aluminum silicide, and titanium silicide. Some examples of metal borides include yttrium boride, aluminum boride, nickel boride, niobium boride, zirconium boride, silicon boride, titanium boride, and cerium boride.

In yet other embodiments, the metal-containing particles have a composite structure (e.g., a core-shell structure) wherein the core is a zerovalent metal and the shell a metal-containing compound (e.g., a metal oxide or any other metal-containing compound described above). For example, the metal-containing particles may possess an iron core encapsulated by an iron oxide shell.

The metal-containing particles can have any of a variety of properties that make them useful for an application of interest. The metal-containing particles may possess a property selected from, for example, a magnetic (which may also be further classified as ferromagnetic, ferrimagnetic, paramagnetic, or superparamagnetic), photovoltaic, photonic, catalytic, sensor, conductive, fluorescent, electroluminescent, superconducting, magnetoresistance, or piezoelectric property.

In some embodiments, any classes or specific types of any of the zerovalent metals or metal compounds described above are excluded from the metal-containing particles or from the metal-carbon composite altogether. In yet other embodiments, alkali or alkaline earth metals are excluded from the metal-containing particles or from the metal-carbon composite altogether.

In some embodiments, the metal-carbon composite is non-porous, while in other embodiments, the metal-carbon composite is porous. In the case of a porous metal-carbon composite, the pores can be located only in the carbon matrix (i.e., with pore walls constructed of carbon matrix), or only in the metal-containing particles (i.e., with pore walls constructed of metal-containing composition), or only at an interface between the carbon matrix and metal-containing particles, or the pores may be located in a combination of these regions (e.g., in the carbon matrix and metal-containing particles or interface). If one or more additional components are included (e.g., carbon particles), the pores may be located at an interface between the carbon matrix and other component, or between the metal-containing particles and other component.

In some embodiments, the metal-carbon composite is mesoporous by containing pores (i.e., mesopores) having a diameter of at least 2 and up to 50 nm. In different embodiments, the mesopores have a uniform or average size of precisely, about, at least, above, up to, or less than, for example, 3 nm, 4 nm, 5 nm, 10 nm, 12 nm, 15 nm, 18 nm, 20 nm, 22 nm, 25 nm, 30 nm, 35 nm, 40 nm, or 45 nm, or a size within a range bounded by any two of the foregoing values, or between any of the foregoing values and 2 nm or 50 nm.

In other embodiments, the metal-carbon composite is microporous by containing pores (i.e., micropores) having a diameter of less than 2 nm. In further embodiments, the micropores may have a diameter of about, precisely, up to, or less than 1.5, 1, or 0.5 nm. If mesopores are also present, the pores present within the composite can be described as being within a size range extending from below 2 nm to any of the mesopore sizes provided above. In some embodiments, micropores may be desirable, whereas in other embodiments, micropores may be not desirable. Micropores may be particularly desirable when the carbon composite is directed to an energy storage application, such as a supercapacitor. In such applications, the larger the micropore volume, the higher the amount of charges that can be stored in these materials. However, micropores may be particularly undesirable when the metal-carbon composite is directed to a liquid flow separation process, because micropores tend to substantially hinder the flow of liquid.

In some embodiments, the metal-carbon composite is macroporous by containing pores (i.e., macropores) having a diameter greater than 50 nm. The macropores may have a uniform or average diameter of about, precisely, up to, less than, at least, or greater than, for example, 60, 70, 80, 90, 100, 150, 200, 250, 300, 350, 400, 450, 500, 600, 700, 800, 900, 1000, 2000, or 5000 nm, or a size within a range bounded by any two of the foregoing values, or between any of the foregoing values and 50 nm. In some embodiments, macropores may be desirable, whereas in other embodiments, macropores may be not desirable. Macropores may be particularly desirable, in some cases, when the carbon composite is directed to a liquid flow separation process, since the larger pores allow for a faster flow rate. If micropores or mesopores are also present, the pores present within the composite can be described as being within a size range extending from below 2 nm, or at or above 2 nm, to any of the macropore sizes provided above.

In some embodiments, the metal-carbon composite or a select component therein (e.g., carbon matrix) contains only mesopores (i.e., 100% pore volume attributed to mesopores), while in other embodiments, the metal-carbon composite or a select component therein includes mesopores and micropores, or mesopores and macropores, or micropores or macropores, or a combination of mesopores, micropores, and macropores. The percent pore volume of each pore size range can be any suitable amount, e.g., precisely, about, at least, above, up to, or less than 1%, 2%, 5%, 10%, 15%, 20%, 25%, 30%, 35%, 40%, 45%, 50%, 55%, 60%, 65%, 70%, 75%, 80%, 85%, 90%, 95%, 98%, or 99% percent pore volume of the total pore volume (the total pore volume sums to 100%). Similarly, particular pore size sub-ranges within the mesopore size range (or within the micropore or macropore size range, if present) can have their own percent pore volumes, such as any of those exemplified above. In some embodiments, micropores and/or macropores, or mesopores of a particular size, are substantially absent. The term “substantially absent” for a particular pore size or pore size range generally means that the indicated pore size or pore size range contributes less than 1%, or up to or less than 0.5%, 0.2%, or 0.1% percent pore volume.

In one set of embodiments, a single distribution of pores is present in the metal-carbon composite or within a select component therein, e.g., carbon matrix. A distribution (or “mode”) of pores is generally defined by a single pore size of maximum (peak) pore volume concentration. Alternatively, the metal-carbon composite may have a bimodal, trimodal, or higher multimodal pore size distribution, which can be identified by the presence of respectively, two, three, or a higher number of peak pore volume concentrations associated with, respectively, one, two, three, or a higher number of individual pore size distributions bounded on each end by a minimum pore size and a maximum pore size. The pore size distributions can be overlapping or non-overlapping. For example, the metal-carbon composite (or a select component therein, e.g., carbon matrix) can include a monomodal, bimodal, trimodal, or higher multimodal mesopore size distribution, wherein each mesopore size distribution is bounded by a minimum mesopore size and maximum mesopore size selected from 2 nm, 3 nm, 4 nm, 5 nm, 6 nm, 7 nm, 8 nm, 9 nm, 10 nm, 12 nm, 15 nm, 20 nm, 25 nm, 30 nm, 35 nm, 40 nm, 45 nm, and 50 nm. Any of the exemplary mesopore sizes provided above can also be taken as a pore size of peak pore volume concentration associated with a particular pore size distribution.

The pores in the metal-carbon composite, or within a select component therein (e.g., carbon matrix) can also possess a level of uniformity, generally either in pore diameter, pore shape, and/or pore interspacing. In particular embodiments, the pores may possess an average pore size corresponding to any of the pore sizes exemplified above, subject to a degree of variation of no more than, for example, ±10 nm, ±8 nm, ±6, nm, ±5 nm, ±4 nm, ±3 nm, ±2 nm, ±1 nm, or ±0.5 nm Particularly for mesopores in the carbon matrix, the mesopores may be arranged relative to each other with a certain degree of order (i.e., in a patterned or ordered arrangement). Some examples of ordered arrangements include a hexagonal or cubic arrangement.

The metal-carbon composite can possess any BET surface area suitable for its intended purpose. The surface area can be, for example, 1, 5, 10, 20, 25, 50, 100, 200, 300, 400, 450, 500, 550, 600, 650, 700, 750, 800, 900, 1000, 1500, or 2000 m²/g, or a surface area within a range bounded by any two of these values. If porous, the metal-carbon composite can possess a pore volume of, for example, 0.1, 0.2, 0.3, 0.4, 0.5, 0.6, 0.7, 0.8, 0.9, 1, 1.5, 2, 2.5, or 3 cm³/g, or a pore volume within a range bounded by any two of these values.

In some embodiments, at least a portion or all of the carbon matrix is non-graphitic, such as amorphous, glassy, or vitreous carbon. In some embodiments, the carbon matrix is no more than, or less than, 80%, 70%, 60%, 50%, 40%, 25%, 20%, 15%, 10%, 5%, 2%, or 1% graphitic, or a percentage therebetween. In some embodiments, substantially all (for example, greater than 90%, 95%, 98%, or 99%) of the carbon matrix is non-graphitic, and may be instead, for example, amorphous or glassy carbon.

In another aspect, the invention is directed to a method of fabricating the metal-carbon composite described above. The method includes subjecting a precursor composition, which contains at least a carbon-forming component and metal-containing particles, to a curing step followed by a carbonization step to produce the metal-carbon composite described above. The precursor composition may be prepared directly prior to the curing and carbonization steps, or prepared at an earlier time and stored for later use.

The precursor composition includes at least the following components: (i) one or more phenolic compounds or materials (i.e., “phenolic component”), (ii) one or more crosslinkable aldehyde compounds or materials (i.e., “aldehyde component”), (iii) a polymerization catalyst, and (iv) metal-containing particles, as described above. The combination of phenolic and aldehyde components (and ultimately, the cured or polymerized form thereof) herein serves the role as carbon-forming component, and may alternatively be referred to as the “carbon precursor”. The carbon precursor is converted to the carbon matrix during the carbonization step. During carbonization, the carbon precursor components (i.e., phenolic and aldehyde components), and optional templating component, together produce the carbon matrix in which the metal-containing particles become embedded.

The phenolic component of the precursor composition can be any phenolic compound or material that can react by a condensation reaction with an aldehydic compound or material (such as formaldehyde) under acidic or basic conditions. Typically, any compound or material containing a hydroxy group bound to an aromatic ring (typically, a phenyl ring) is suitable for the present invention as a phenolic compound or material.

In one embodiment, the phenolic compound or material contains one hydroxy group bound to a benzene ring. The benzene ring may be otherwise unsubstituted (i.e., the compound “phenol”), or the benzene ring may be substituted with one or more groups, such as one or more groups selected from hydrocarbon, halide, nitro, amino, hydroxy, and alkoxy groups. Some examples of phenolic compounds include phenol, the halophenols, the aminophenols, the hydrocarbyl-substituted phenols (wherein “hydrocarbyl” includes, e.g., straight-chained, branched, or cyclic alkyl, alkenyl, or alkynyl groups typically containing from 1 to 6 carbon atoms, optionally substituted with one or more oxygen or nitrogen atoms), naphthols, nitrophenols, hydroxyanisoles, hydroxybenzoic acids, fatty acid ester-substituted or polyalkyleneoxy-substituted phenols (e.g., on the 2 or 4 positions with respect to the hydroxy group), phenols containing an azo linkage (e.g., p-hydroxyazobenzene), phenolsulfonic acids (e.g., p-phenolsulfonic acid), and dihydroxybiphenyls. Some general subclasses of halophenols include the fluorophenols, chlorophenols, bromophenols, and iodophenols, and their further sub-classification as, for example, p-halophenols (e.g., 4-fluorophenol, 4-chlorophenol, 4-bromophenol, and 4-iodophenol), m-halophenols (e.g., 3-fluorophenol, 3-chlorophenol, 3-bromophenol, and 3-iodophenol), o-halophenols (e.g., 2-fluorophenol, 2-chlorophenol, 2-bromophenol, and 2-iodophenol), dihalophenols (e.g., 3,5-dichlorophenol and 3,5-dibromophenol), and trihalophenols (e.g., 3,4,5-trichlorophenol, 3,4,5-tribromophenol, 3,4,5-trifluorophenol, 3,5,6-trichlorophenol, and 2,3,5-tribromophenol). Some examples of aminophenols include 2-, 3-, and 4-aminophenol, and 3,5- and 2,5-diaminophenol. Some examples of nitrophenols include 2-, 3-, and 4-nitrophenol, and 2,5- and 3,5-dinitrophenol. Some examples of hydrocarbyl-substituted phenols include the cresols, i.e., methylphenols or hydroxytoluenes (e.g., o-cresol, m-cresol, p-cresol), the xylenols (e.g., 3,5-, 2,5-, 2,3-, and 3,4-dimethylphenol), the ethylphenols (e.g., 2-, 3-, and 4-ethylphenol, and 3,5- and 2,5-diethylphenol), n-propylphenols (e.g., 4-n-propylphenol), isopropylphenols (e.g., 4-isopropylphenol), butylphenols (e.g., 4-n-butylphenol, 4-isobutylphenol, 4-t-butylphenol, 3,5-di-t-butylphenol, 2,5-di-t-butylphenol), hexylphenols, octyl phenols (e.g., 4-n-octylphenol), nonylphenols (e.g., 4-n-nonylphenol), phenylphenols (e.g., 2-phenylphenol, 3-phenylphenol, and 4-phenylphenol), and hydroxycinnamic acid (p-coumaric acid). Some examples of hydroxyanisoles include 2-methoxyphenol, 3-methoxyphenol, 4-methoxyphenol, 3-t-butyl-4-hydroxyanisole (e.g., BHA), and ferulic acid. Some examples of hydroxybenzoic acids include 2-hydroxybenzoic acid (salicylic acid), 3-hydroxybenzoic acid, 4-hydroxybenzoic acid, and their organic acid esters (e.g., methyl salicylate and ethyl-4-hydroxybenzoate).

In another embodiment, the phenolic compound or material contains two phenol groups, i.e. two hydroxy groups bound to a benzene ring, or two hydroxy groups bound to different benzene rings of the same molecule. Some examples of such compounds include catechol, resorcinol, dihydroquinone, the hydrocarbyl-linked bis-phenols (e.g., bis-phenol A, methylenebisphenol, and 4,4′-dihydroxystilbene), the dihydroxybiphenyls (e.g., 4,4′-dihydroxybiphenyl, or 4,4′-biphenol), the halo-substituted diphenols (e.g., 2-haloresorcinols, 3-haloresorcinols, and 4-haloresorcinols, wherein the halo group can be fluoro, chloro, bromo, or iodo), the amino-substituted diphenols (e.g., 2-aminoresorcinol, 3-aminoresorcinol, and 4-aminoresorcinol), the hydrocarbyl-substituted diphenols (e.g., 2,6-dihydroxytoluene, i.e., 2-methylresorcinol; 2,3-, 2,4-, 2,5-, and 3,5-dihydroxytoluene, 1-ethyl-2,6-dihydroxybenzene, caffeic acid, and chlorogenic acid), the nitro-substituted diphenols (e.g., 2- and 4-nitroresorcinol), dihydroxyanisoles and their ether derivatives (e.g., 3,5-, 2,3-, 2,5-, and 2,6-dihydroxyanisole, and vanillin), dihydroxybenzoic acids and their ether derivatives (e.g., 3,5-, 2,3-, 2,5-, and 2,6-dihydroxybenzoic acid, and their alkyl esters, and vanillic acid), and phenolphthalein.

In another embodiment, the phenolic compound or material contains three phenol groups, i.e. three hydroxy groups bound to a benzene ring, or three hydroxy groups bound to different benzene rings of the same molecule. Some examples of such compounds include phloroglucinol (1,3,5-trihydroxybenzene), pyrogallol (1,2,3-trihydroxybenzene), 1,2,4-trihydroxybenzene, 5-chloro-1,2,4-trihydroxybenzene, resveratrol (trans-3,5,4′-trihydroxystilbene), the hydrocarbyl-substituted triphenols (e.g., 2,4,6-trihydroxytoluene, i.e., methylphloroglucinol, and 3,4,5-trihydroxytoluene), the halogen-substituted triphenols (e.g., 5-chloro-1,2,4-trihydroxybenzene), the carboxy-substituted triphenols (e.g., 3,4,5-trihydroxybenzoic acid, i.e., gallic acid or quinic acid, and 2,4,6-trihydroxybenzoic acid), the nitro-substituted triphenols (e.g., 2,4,6-trihydroxynitrobenzene), and phenol-formaldehyde resoles or novolak resins containing three phenol groups.

In yet another embodiment, the phenolic compound or material contains multiple (i.e., greater than three) phenol groups. Some examples of such compounds or materials include quercetin, ellagic acid, and tetraphenol ethane, as well as phenol-containing macromolecules generally having a molecular weight of at least or above 1000 g/moles, such as tannin (e.g., tannic acid), tannin derivatives (e.g., ellagotannins and gallotannins), phenol-containing polymers (e.g., poly-(4-hydroxystyrene)), phenol-formaldehyde resoles or novolak resins, phenol-containing porphyrins, and calixarenes.

In some embodiments, any one or more classes or specific types of phenolic compounds or materials described above are excluded from the precursor composition or preparative method described herein. In other embodiments, a combination of phenolic compounds or materials described above may used in the precursor composition.

The crosslinkable aldehyde component of the precursor composition can be any organic compound or material containing an aldehyde group. In many embodiments, the crosslinkable aldehyde is formaldehyde. However, there are also numerous organoaldehydes, organodialdehydes, and polyaldehydes (e.g., organotrialdehydes, organotetraaldehydes, and so on) considered herein which can serve the same purpose. The organoaldehydes can be generally represented by the following formula:

R—CHO (1)

In Formula (1), R can represent a straight-chained, branched, or cyclic hydrocarbyl group, which can be either saturated or unsaturated, typically containing at least 1, 2, or 3 carbon atoms, and up to 4, 5, 6, 7, or 8 carbon atoms. Some examples of suitable organoaldehydes include acetaldehyde, propanal (propionaldehyde), butanal (butyraldehyde), pentanal (valeraldehyde), hexanal, crotonaldehyde, acrolein, benzaldehyde, and furfural.

The organodialdehydes can be generally represented by the following formula:

OHC—R—CHO (2)

wherein R is a bond or a straight-chained, branched, or cyclic hydrocarbyl linking group, which can be either saturated or unsaturated, typically containing at least 1, 2, or 3 carbon atoms, and up to 4, 5, 6, 7, 8, 9, or 10 carbon atoms. Some examples of dialdehyde compounds include glyoxal (when R is a bond), malondialdehyde (when R is methylene), succinaldehyde, glutaraldehyde, adipaldehyde, pimelaldehyde, suberaldehyde, sebacaldehyde, cyclopentanedialdehyde, terephthaldehyde, and furfuraldehyde. In some embodiments, one of the aldehydic hydrogens of a dialdehyde can be replaced with a hydrocarbyl group, thereby resulting in an aldehyde-ketone dione compound, such as methylglyoxal or 1,3-butanedione.

In some embodiments, any one or more classes or specific types of aldehyde compounds or materials described above are excluded from the precursor composition or preparative method described herein. In other embodiments, a combination of aldehyde compounds or materials described above may used in the precursor composition.

The polymerization catalyst can be any of the catalysts known in the art for effecting polymerization between phenolic and aldehydic components, typically an acid or base. In the case of an acid, the acid catalyst can be any acid strong enough to facilitate the reaction between phenolic and aldehydic compounds. In some embodiments, the acid is a weak acid, such as a weak organic acid (e.g., oxalic acid, acetic acid, propionic acid, or citric acid) or a weak inorganic acid (e.g., phosphoric acid). In other embodiments, the acid is a strong acid, such as a mineral acid, such as hydrochloric acid, hydrobromic acid, hydroiodic acid, sulfuric acid, or a superacid, such as triflic acid. In the case of a base, the alkaline catalyst can be any base strong enough to facilitate the reaction between phenolic and aldehydic compounds. The base can be, for example, an alkali metal hydroxide (e.g., sodium hydroxide or potassium hydroxide), a metal carbonate or bicarbonate (e.g., Na₂CO₃, K₂CO₃, NaHCO₃, CaCO₃), or a tertiary amine, such as triethanolamine or alkyldiethanolamine. Depending on the type of acid or base, and other conditions, the molar concentration of acid or base (per total precursor composition) can be, for example, precisely, about, at least, up to, or less than, for example, 0.1 molar (i.e., 0.1 M), 0.2 M, 0.5 M, 1.0 M, 1.5 M, 2.0 M, 2.5 M, 3.0 M, 3.5 M, 4.0 M, 4.5 M, 5.0M, or an acid or base concentration within a range bounded by any two of the foregoing values. The molar concentration values given may also be referred to in terms of molar equivalents of H⁺, or pH, wherein the pH for a strong acid generally abides by the formula pH=−log [H⁺], wherein [H⁺] represents the concentration of H⁺ ions. In some embodiments, any one or more classes or specific types of acids or bases described above are excluded from the preparative method described herein.

In some embodiments, the molar amount of crosslinkable aldehyde component is higher than the molar amount of phenolic component (i.e., molar ratio of aldehyde to phenolic components is greater than 1). In such embodiments, the molar ratio of aldehyde to phenolic components may be precisely, about, or at least, for example, 1.1, 1.2, 1.3, 1.4, 1.5, 1.6, 1.7, 1.8, 1.9, 2.0, 2.1, 2.2, 2.3, 2.4, 2.5, 2.6, 2.7, 2.8, 2.9, or 3.0, or within a range bounded by any two of these values. In other embodiments, the molar amount of aldehyde component is less than the molar amount of phenolic component (i.e., molar ratio of aldehyde to phenolic components is less than 1). In such embodiments, the molar ratio of aldehyde to phenolic components may be precisely, about, or less than, for example, 0.9, 0.8, 0.7, 0.6, 0.5, 0.4, 0.3, or 0.2, or within a range bounded by any two of these values. In other embodiments, the molar amount of aldehyde component is about the same as the molar amount of phenolic component, i.e., a ratio of about 1.

Any one or more or all of the above components in the precursor composition can be dissolved, dispersed, or suspended in a suitable solvent, wherein it is understood that at least the metal-containing particles are not dissolved, since their form must be retained to be ultimately embedded in the carbon matrix. The solvent can be, for example, an organic polar protic or non-protic solvent. Some examples of organic polar protic solvents include the alcohols, e.g., methanol, ethanol, n-propanol, isopropanol, ethylene glycol, and the like. Some examples of organic polar non-protic solvents include acetonitrile, dimethylformamide, dimethylsulfoxide, methylene chloride, organoethers (e.g., tetrahydrofuran or diethylether), and the like. The solvent can also be an ionic liquid, such as an imidazolium or piperidinium ionic liquid. In some embodiments, any one or more of the above classes or specific types of solvents can be excluded from the precursor composition.

The precursor composition may or may not further include a liquid or solid porogenic material (i.e., porogen), which produces pores in the resulting metal-carbon composite either by being volatized during the curing or carbonization process, or by chemical removal. In some embodiments, a solvent or other liquid component is included to function as a porogen. In other embodiments, the porogen is a solid particulate material that produces volatile gases (typically, with low char) upon thermal activation. Some examples of such porogens include polymeric compositions, such as polyethylene, polypropylene, polyethylene oxide (PEO), polypropylene oxide (PPO), and block copolymers thereof, and volatile compounds, such as waxes. In other embodiments, the porogen is a solid particulate material that can be chemically removed post-curing or post-carbonization by, for example, dissolution by a solvent or reaction with another substance. An example of such a porogen is silicon oxide, which can be removed by reaction with hydrofluoric acid.

The precursor composition may or may not further include a templating agent. The templating component functions to organize the polymer precursor materials in an ordered (i.e., patterned) arrangement during the curing process before the carbonization step. Typically, the templating component is a substance (e.g., compound or polymer) that possesses at least two separate functionalities that interact differently with the phenolic and formaldehyde components. The functionalities can interact differently by a difference in hydrophobicity, hydrophilicity, or functional activity. By virtue of the ordered arrangement provided by the templating component during the curing process, the resulting metal-carbon composite can include an ordered arrangement of the metal particles and/or pores (if present) therein. Such ordered arrangements may be beneficial, and in some cases critical, for certain applications, such as photovoltaics, photonics, and catalysts.

In particular embodiments, the templating component is a copolymer, which may be, for example, a block, alternating, random, or graft copolymer. The copolymer may be completely inorganic (i.e., does not contain carbon), completely organic (i.e., composed of carbon and elements selected from hydrogen and Groups 15-17 of the Periodic Table), or an organic-inorganic hybrid material, such as a hybrid sol-gel.

In particular embodiments, the copolymer is a block copolymer, which is herein understood to be a polymer containing two or more chemically distinct polymeric blocks (sections or segments). The copolymer can be, for example, a diblock copolymer (e.g., A-B), triblock copolymer (e.g., A-B-C), tetrablock copolymer (e.g., A-B-C-D), or higher block copolymer, wherein A, B, C, and D represent chemically distinct polymeric segments. In some embodiments, the block copolymer contains at least two segments that possess a difference in hydrophilicity or hydrophobicity (i.e., is amphiphilic). Such block copolymers typically form periodic structures by virtue of selective interactions between like domains, i.e., between hydrophobic domains and between hydrophilic domains. The block copolymer is typically linear; however, branched (e.g., glycerol branching units) and grafted block copolymer variations are also contemplated herein. In some embodiments, the block copolymer contains polar groups capable of interacting (e.g., by hydrogen or ionic bonding) with the phenolic compound or material. For this reason, the block copolymer is typically not a complete hydrocarbon as in the case of styrene-butadiene polymers. Some of the groups preferably located in the block copolymer that can provide a favorable interactive bond with phenol groups include, for example, hydroxy, amino, imino, and carbonyl groups.

Some general examples of suitable classes of block copolymers include those containing segments of polyacrylate or polymethacrylate (and esters thereof), polystyrene, polyethyleneoxide, polypropyleneoxide, polyethylene, polyacrylonitrile, polylactide, and polycaprolactone. Some specific examples of suitable block copolymers include polystyrene-b-poly(methylmethacrylate) (i.e., PS-PMMA), polystyrene-b-poly(acrylic acid) (i.e., PS-PAA), polystyrene-b-poly(4-vinylpyridine) (i.e., PS-P4VP), polystyrene-b-poly(2-vinylpyridine) (i.e., PS-P2VP), polyethylene-b-poly(4-vinylpyridine) (i.e., PE-P4VP), polystyrene-b-polyethyleneoxide (i.e., PS-PEO), polystyrene-b-poly(4-hydroxystyrene), polyethyleneoxide-b-polypropyleneoxide (i.e., PEO-PPO), polyethyleneoxide-b-poly(4-vinylpyridine) (i.e., PEO-P4VP), polyethylene-b-polyethyleneoxide (i.e., PE-PEO), polystyrene-b-poly(D,L-lactide), polystyrene-b-poly(methylmethacrylate)-b-polyethyleneoxide (i.e., PS-PMMA-PEO), polystyrene-b-polyacrylamide, polystyrene-b-polydimethylacrylamide (i.e., PS-PDMA), polystyrene-b-polyacrylonitrile (i.e., PS-PAN), and polyethyleneoxide-b-polyacrylonitrile (i.e., PEO-PAN).

In some embodiments, the block copolymer is a triblock copolymer containing one or more poly-EO segments and one or more poly-PPO segments. More particularly, the triblock copolymer can be a poloxamer (i.e. Pluronic® or Lutrol® polymer) according to the general formula

(PEO)ₐ-(PPO)_{b}-(PEO)_{c} (3)

In Formula (3), PEO is a polyethylene oxide block (i.e., —CH₂CH₂O—) and PPO is a polypropylene block (i.e., —CH₂CH(CH₃)O— or —CH(CH₃)CH₂O—), and the subscripts a, b, and c represent the number of monomer units of PEO and PPO, as indicated. Typically, a, b, and c in Formula (3) are each at least 2, and more typically, at least 5, and typically up to a value of 100, 120, or 130. Subscripts a and c are typically of equal value in these types of polymers. In different embodiments, a, b, and c can independently have a value of about, or at least, or up to 10, 20, 30, 40, 50, 60, 70, 80, 90, 100, 120, 130, 140, 150, 160, 180, 200, 220, 240, or any particular range established by any two of these exemplary values.

In one embodiment, a and c values in Formula (3) are each less than b, i.e., the hydrophilic PEO block is shorter on each end than the hydrophobic PPO block. For example, in different embodiments, a, b, and c can each independently have a value of 2, 5, 7, 10, 12, 15, 20, 25, 30, 35, 40, 45, 50, 55, 60, 65, 70, 75, 80, 85, 90, 95, 100, 110, 120, 130, 140, 150, or 160, or any range delimited by any two of these values, provided that a and c values are each less than b. Furthermore, in different embodiments, it can be preferred for the a and c values to be less than b by a certain number of units, e.g., by 2, 5, 7, 10, 12, 15, 20, 25, 30, 35, 40, 45, or 50 units, or any range therein. Alternatively, it can be preferred for the a and c values to be a certain fraction or percentage of b (or less than or greater than this fraction or percentage), e.g., about 10%, 20%, 25%, 30, 33%, 40%, 50%, 60%, 70%, 75%, 80%, 85%, 90%, or any range delimited by any two of these values.

In another embodiment, a and c values in Formula (3) are each greater than b, i.e., the hydrophilic PEO block is longer on each end than the hydrophobic PPO block. For example, in different embodiments, a, b, and c can each independently have a value of 2, 5, 7, 10, 12, 15, 20, 25, 30, 35, 40, 45, 50, 55, 60, 65, 70, 75, 80, 85, 90, 95, 100, 110, 120, 130, 140, 150, or 160, or any range delimited by any two of these values, provided that a and c values are each greater than b. Furthermore, in different embodiments, it can be preferred for the a and c values to be greater than b by a certain number of units, e.g., by 2, 5, 7, 10, 12, 15, 20, 25, 30, 35, 40, 45, or 50 units, or any range therein. Alternatively, it can be preferred for the b value to be a certain fraction or percentage of a and c values (or less than or greater than this fraction or percentage), e.g., about 10%, 20%, 25%, 30, 33%, 40%, 50%, 60%, 70%, 75%, 80%, 85%, 90%, or any range delimited by any two of these values.

In different embodiments, the templating agent (or more particularly, the copolymer) has an average molecular weight of at least or greater than 500, 800, 1000, 1200, 1500, 2000, 2500, 3000, 3500, 4000, or 4500 g/mole, and/or an average molecular weight of up to or less than 5000, 5500, 6000, 6500, 7000, 7500, 8000, 8500, 9000, 9500, 10,000, 12,000, 15,000, or 20,000 g/mole, or a molecular weight within a range bounded by any two of the foregoing values. The viscosity of the polymers is generally at least 200, 250, 300, 350, 400, 450, 500, 550, 600, or 650 centipoise (cps), and generally up to 700, 800, 900, 1000, 1500, 2000, 2500, 3000, 3500, 4000, 4500, 5000, 5500, 6000, 6500, 7000, or 7500 cps.

The following table lists several exemplary poloxamer polymers applicable to the present invention.

TABLE 1
Some exemplary poloxamer polymers

| | | Approxi- | Approxi- | Approxi- |
|---|---|---|---|---|
| Generic | Pluronic ® | mate val- | mate val- | mate val- |
| Name | Name | ue of a | ue of b | ue of c |
| Poloxamer 101 | Pluronic L-31 | 2 | 16 | 2 |
| Poloxamer 105 | Pluronic L-35 | 11 | 16 | 11 |
| Poloxamer 108 | Pluronic F-38 | 46 | 16 | 46 |
| Poloxamer 122 | — | 5 | 21 | 5 |
| Poloxamer 123 | Pluronic L-43 | 7 | 21 | 7 |
| Poloxamer 124 | Pluronic L-44 | 11 | 21 | 11 |
| Poloxamer 181 | Pluronic L-61 | 3 | 30 | 3 |
| Poloxamer 182 | Pluronic L-62 | 8 | 30 | 8 |
| Poloxamer 183 | — | 10 | 30 | 10 |
| Poloxamer 184 | Pluronic L-64 | 13 | 30 | 13 |
| Poloxamer 185 | Pluronic P-65 | 19 | 30 | 19 |
| Poloxamer 188 | Pluronic F-68 | 75 | 30 | 75 |
| Poloxamer 212 | — | 8 | 35 | 8 |
| Poloxamer 215 | — | 24 | 35 | 24 |
| Poloxamer 217 | Pluronic F-77 | 52 | 35 | 52 |
| Poloxamer 231 | Pluronic L-81 | 6 | 39 | 6 |
| Poloxamer 234 | Pluronic P-84 | 22 | 39 | 22 |
| Poloxamer 235 | Pluronic P-85 | 27 | 39 | 27 |
| Poloxamer 237 | Pluronic F-87 | 62 | 39 | 62 |
| Poloxamer 238 | Pluronic F-88 | 97 | 39 | 97 |
| Poloxamer 282 | Pluronic L-92 | 10 | 47 | 10 |
| Poloxamer 284 | — | 21 | 47 | 21 |
| Poloxamer 288 | Pluronic F-98 | 122 | 47 | 122 |
| Poloxamer 331 | Pluronic L-101 | 7 | 54 | 7 |
| Poloxamer 333 | Pluronic P-103 | 20 | 54 | 20 |
| Poloxamer 334 | Pluronic P-104 | 31 | 54 | 31 |
| Poloxamer 335 | Pluronic P-105 | 38 | 54 | 38 |
| Poloxamer 338 | Pluronic F-108 | 128 | 54 | 128 |
| Poloxamer 401 | Pluronic L-121 | 6 | 67 | 6 |
| Poloxamer 403 | Pluronic P-123 | 21 | 67 | 21 |
| Poloxamer 407 | Pluronic F-127 | 98 | 67 | 98 |

As known in the art, the names of the poloxamers and Pluronics (as given above) contain numbers that provide information on the chemical composition. For example, the generic poloxamer name contains three digits, wherein the first two digits×100 indicates the approximate molecular weight of the PPO portion and the last digit×10 indicates the weight percent of the PEO portion. Accordingly, poloxamer 338 possesses a PPO portion of about 3300 g/mole molecular weight, and 80 wt % PEO. In the Pluronic name, the letter indicates the physical form of the product, i.e., L=liquid, P=paste, and F=solid, i.e., flake. The first digit, or two digits for a three-digit number, multiplied by 300, indicates the approximate molecular weight of the PPO portion, while the last digit×10 indicates the weight percent of the PEO portion. For example, Pluronic® F-108 (which corresponds to poloxamer 338) indicates a solid form composed of about 3,000 g/mol of the PPO portion and 80 wt % PEO.

Numerous other types of copolymers containing PEO and PPO blocks are possible, all of which are applicable herein. For example, the block copolymer can also be a reverse poloxamer of general formula:

(PPO)ₐ-(PEO)_{b}-(PPO)_{c} (4)

wherein all of the details considered above with respect to the regular poloxamers (e.g., description of a, b, and c subscripts, and all of the other exemplary structural possibilities) are applicable by reference herein to the reverse poloxamers.

In another variation, the block copolymer contains a linking diamine group (e.g., ethylenediamine, i.e., EDA) or triamine group (e.g., melamine). Some examples of such copolymers include the Tetronics® (e.g., PEO-PPO-EDA-PPO-PEO) and reverse Tetronics® (e.g., PPO-PEO-EDA-PEO-PPO).

In some embodiments, the templating component also functions as a porogen. For example, during carbonization, the block copolymers described above typically also function as porogens by becoming volatized into gaseous byproducts, without contributing to formation of the carbon matrix. The volatile gases produced from the block copolymer typically create mesopores (and may or may not also produce micropores) in the carbon matrix during the curing and/or carbonization steps.

In some embodiments, two or more types of porogens and/or templating components are included in the precursor composition. In other embodiments, any one or more classes or specific types of block copolymers or other templating components or porogens described above are excluded from the precursor composition.

The precursor composition may or may not also include carbon particles. The carbon particles may independently have any of the sizes described above for the metal-containing particles. Thus, the carbon particles may be nanoparticles, microparticles, or macroparticles. The carbon particles may be conductive or non-conductive, and may be graphitic or non-graphitic. In some embodiments, the carbon particles are any of the carbon particles known in the art that are conductive, generally by virtue of a graphitic structure.

Some examples of carbon particles include carbon black, graphite powder, chopped carbon fiber, activated carbon, the fullerenes, carbon onion, carbon nanodiamond, carbon aerogel, carbon nanofoam, and carbon nanobuds, all of which have compositions and physical and electrical properties well-known in the art. The fullerenes can be categorized as spherical fullerenes (e.g., buckminsterfullerene, i.e., C₆₀, as well as any of the smaller or larger buckyballs, such as C₂₀ or C₇₀) or tubular fullerenes (e.g., single-walled, double-walled, or multi-walled carbon nanotubes). When a carbon black is used, it may be a conductive carbon black, such as an acetylene black. In the case of carbon nanodiamonds, these are generally electronic insulators and good thermal conductors, unless they are thermally treated above 1000° C., under which condition a graphitization process begins from the outer layers to the interior of the nanodiamond particles. Nanodiamonds with a graphitic outer shell are electronic conductors. As known in the art, fully graphitized carbon nanodiamonds can be considered to be carbon onions. In the case of chopped carbon fiber, the carbon fiber may be any of the carbon fibers well known in the art, such as those produced by pyrolysis of polyacrylonitrile (PAN) or a polyolefin, such as polyethylene or polypropylene.

In some embodiments, the carbon particles are made exclusively of carbon, while in other embodiments, the carbon particles can include an amount of one or a combination of non-carbon non-hydrogen (i.e., hetero-dopant) elements, such as nitrogen, oxygen, sulfur, boron, phosphorus, or a metal, such as an alkali metal (e.g., lithium), alkaline earth metal, transition metal, main group metal (e.g., Al, Ga, or In), or rare earth metal. The amount of hetero element can be a minor amount (e.g., up to 0.1, 0.5, 1, 2, or 5 wt % or mol %) or a more substantial amount (e.g., about, at least, or up to 10, 15, 20, 25, 30, 40, or 50 wt % or mol %). The carbon particles may also have a metal carbide composition, such as a SiC or WC composition.

In different embodiments, the amount of carbon particles can be included in the precursor composition in an amount of about, at least, above, up to, or less than, for example, 1 wt %, 2 wt %, 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, 70 wt %, 75 wt %, 80 wt %, 85 wt %, or 90 wt % by weight of the precursor composition, or an amount within a range bounded by any two of the foregoing exemplary values.

In the method for producing the metal-carbon composite, the above-described precursor composition, which includes at least (i) a phenolic component, (ii) a crosslinkable aldehyde component, (iii) a polymerization catalyst, and (iv) metal-containing particles, is subjected to a curing step followed by a carbonization step. The particulate nature of the metal-containing particles should be maintained through the curing and carbonization process such that they should remain as particles in the carbonized product. Although the metal-containing particles retain their shape as particles through curing and carbonization, the composition of the particles may or may not change after processing by curing and carbonization. For example, iron or nickel particles may form a coating of iron oxide or nickel oxide, respectively, or be completely converted to these forms, after a curing or carbonization process conducted in the presence of oxygen and at sufficient temperature. In some embodiments, measures can be taken to prevent a change in composition of the particles, such as by conducting the curing and carbonization steps under an inert atmosphere and/or at lower temperatures.

After the precursor components are all combined, the combined mixed components are subjected to a curing step to convert the mixture to a crosslinked gel or solid material. The curing step includes any of the conditions, as known in the art, that promote polymerization, and preferably, crosslinking, of polymer precursors, and in particular, crosslinking between phenolic and aldehydic components to form a solid crosslinked carbon precursor. The curing conditions generally include application of an elevated temperature for a specified period of time without significant carbonization (or any carbonization) of the precursor. Other curing conditions and methods can be used in the curing step, including radiative (e.g., UV curing) or purely chemical (i.e., without use of an elevated temperature). Generally, the curing step involves subjecting the polymer precursors or the entire precursor composition to a temperature of about, at least, up to, or less than 60, 70, 80, 90, 100, 110, 120, 130, 140° C., 150° C., 160° C., 170° C., 180° C., 190° C., or 200° C. for a time period of, typically, at least 0.5, 1, 2, 5, 10, or 12 hours and up to 15, 20, 24, 36, 48, or 72 hours, wherein it is understood that higher temperatures generally require shorter time periods to achieve the same or similar result. Alternatively, the curing temperature is within a range bounded by any two of the exemplary curing temperatures recited above.

In some embodiments, it may be preferred to subject the precursors to an initial lower temperature curing step followed by a higher temperature curing step. The initial curing step may employ a temperature of, for example, 60, 70, 80, 90, or 100° C. (or a range between any of these), while the subsequent curing step may employ a temperature of, for example, 90, 100, 110, 120, 130, 140° C., 150° C., 160° C., 170° C., 180° C., 190° C., or 200° C. (or a range between any of these), provided that the temperature of the initial curing step is less than the temperature of the subsequent curing step. In addition, each curing step can independently employ any of the exemplary time periods given above.

Alternatively, it may be preferred to gradually increase the temperature during the curing step between any of the temperatures given above, or between room temperature (e.g., 15, 20, 25, 30, or 35° C.) and any of the temperatures given above. In different embodiments, the gradual increase in temperature can be practiced by employing a temperature ramp rate of, or at least, or no more than 1° C./min, 2° C./min, 3° C./min, 5° C./min, 7° C./min, 10° C./min, 12° C./min, 15° C./min, 20° C./min, or 30° C./min, or within a range bounded by any two of these values. The gradual temperature increase can also include one or more periods of residency at a particular temperature, and/or a change in the rate of temperature increase.

The carbonization step includes any of the conditions, as known in the art, that cause carbonization of a carbon-containing composition. Generally, the carbonization process employs a temperature of at least 300° C. and up to or less than 2000° C. In different embodiments, a carbonization temperature of at least or above 300° C., 350° C., 400° C., 450° C., 500° C., 550° C., 600° C., 650° C., 700° C., 750° C., 800° C., 850° C., 900° C., 950° C., 1000° C., 1050° C., 1100° C., 1150° C., 1200° C., 1250° C., 1300° C., 1350° C., 1400° C., 1450° C., 1500° C., 1600° C., 1700° C., 1800° C., 1900° C., or 2000° C. is employed for a time period of, typically, at least 1, 2, 3, 4, 5, or 6 hours and up to 7, 8, 9, 10, 11, or 12 hours, wherein it is understood that higher temperatures generally require shorter time periods to achieve the same or similar result. The carbonization temperature may also be selected from a range bounded by any two exemplary carbonization temperatures recited above.

In some embodiments, it may be preferred to subject the precursors to an initial lower temperature carbonization step followed by a higher temperature carbonization step. The initial carbonization step may employ a temperature of, for example, 300, 350, 400, 450, 500, 550, 600, 650, 700, 750, 800, 850, or 900° C. (or a range between any of these), while the subsequent carbonization step may employ a temperature of, for example, 500, 550, 600, 650, 700, 750, 800, 850, 900, 950, 1000, 1050, 1100, 1200, 1250, 1300, 1400, 1450, 1500, 1600, 1700, 1900° C., or 2000° C. (or a range between any of these), provided that the temperature of the initial carbonization step is less than the temperature of the subsequent carbonization step. In addition, each carbonization step can independently employ any of the exemplary time periods given above.

Alternatively, it may be preferred to gradually increase the temperature during the carbonization step between any of the carbonization temperatures given above, or between room temperature (e.g., 15, 20, 25, 30, or 35° C.) or any of the curing temperatures provided above and any of the carbonization temperatures given above. Thus, in some embodiments, a curing step and carbonization step may be performed continuously, one after the other, with no clear boundary between the steps. In different embodiments, the gradual increase in temperature can be practiced by employing a temperature ramp rate of, or at least, or no more than 1° C./min, 2° C./min, 3° C./min, 5° C./min, 7° C./min, 10° C./min, 12° C./min, 15° C./min, 20° C./min, 30° C./min, 40° C./min, or 50° C./min, or within a range bounded by any two of these values. The gradual temperature increase can also include one or more periods of residency at a particular temperature, and/or a change in the rate of temperature increase.

In some embodiments, a graphitization step may be employed to increase the graphitic character of the carbon matrix. Thus, if desired, the precursor composition or the carbonized material can be subjected to a graphitization step. Typically, the temperature for inducing graphitization is a temperature of at least or greater than about 2000° C., 2100° C., 2200° C., 2300° C., 2400° C., 2500° C., 2600° C., 2700° C., 2800° C., 2900° C., 3000° C., 3100° C., or 3200° C., or a temperature within a range bounded by any two of these temperatures, typically for a time period of or less than, for example, 10, 20, or 30 minutes, or any of the time periods provided above. Typically, unless oxidation is desired, the carbonization or graphitization step is conducted in an atmosphere substantially removed of oxygen, e.g., typically under an inert atmosphere. Some examples of inert atmospheres include nitrogen and the noble gases (e.g., helium or argon). Some conditions that generally favor graphitization (e.g., inclusion of catalytic species, such as iron (III) complexes) may be included, but can also be excluded in some embodiments.

In some embodiments, after combining at least the polymeric, aldehydic, and catalyst components of the precursor composition, and before curing or carbonization, the solution is stirred for a sufficient period of time (e.g., at least or about 1, 2, 5, 10, 20, 30, 40, 50, 60, 90, or 120 minutes, or a range between any these values) until a phase separation or precipitation is evident. In some cases, the solution turns turbid. The turbidity generally indicates formation of an ordered nanocomposite gel or solid that has undergone a degree of phase separation from the liquid portion of the solution. If desired, stirring can be continued after the onset of turbidity, such that the total amount of stirring time before curing, carbonization, or a phase-separation process is any of the exemplary time periods given above, or a much longer period of time, such as several hours (e.g., at least or about 4, 5, 6, 7, 8, 10, or 12 hours) or days (e.g., at least or about 1, 2, 3, 4, 5, 10, 15, or 20 days), or a range between of the foregoing exemplary periods of time.

After turbidity becomes evident, the phase-separated mixture can be subjected to conditions that cause the polymerized precursor material to be substantially separated or isolated from the liquid portion. Any separation method can be applied herein. In some embodiments, the phases are separated by centrifugation. In different embodiments, the centrifugation can be conducted at an angular speed of or at least, for example, 2000 rpm, 2500 rpm, 3000 rpm, 4000 rpm, 5000 rpm, 6000 rpm, 7000 rpm, 8000 rpm, 9000 rpm, 9500 rpm, 10000 rpm, 11000 rpm, 12000 rpm, or 15000 rpm, or a range between any of these values, for a period of time of, for example, 0.1, 0.2, 0.5, 1, 2, 3, 4, 5, 10, or 15 minutes, wherein it is understood that higher angular speeds generally require less amounts of time to effect an equivalent degree of separation. Superspeed centrifugation (e.g., up to 20,000 or 30,000 rpm) or ultracentrifugation (e.g., up to 40,000, 50,000, 60,000, or 70,000 rpm) can also be used. The gel or solid phase, once separated from the liquid phase, can be cured and carbonized in the substantial absence of the liquid phase according to any of the conditions described above for these processes. In the case where the metal-containing particles were not originally included in the turbidified or phase-separated precursor, the metal-containing particles (and optionally, carbon particles) may be added and mixed after the onset of turbidity or phase-separation, or the metal-containing particles may be added and mixed with the polymerized precursor material after it has been separated or isolated from the liquid.

In some embodiments, the pre-cured gel or viscous solid phase, which includes at least components (i)-(iv) described above, is cast onto a solid substrate to make a film (i.e., coating) of the pre-cured gel or viscous solid on the substrate. The precursor composition can be deposited by any suitable means known in the art to produce a film (i.e., coating) of the precursor composition on the substrate. Some examples of solution deposition processes include spin-coating, brush coating (painting), spraying, and dipping. After being deposited, the precursor film is subsequently cured and then carbonized to form the carbon composite, described above, on the substrate. One or more solvents, such as any of those described above, may be included in sufficient quantity to make the precursor solution or pre-cured gel of sufficiently low viscosity (i.e., liquid) so as to be applied by a suitable application method to a substrate.

The substrate on which the precursor composition is deposited can be any useful substrate known in the art, including functional substrates and sacrificial substrates. The choice of functional substrate is very much dependent on the ultimate application. Generally, the substrate should be sufficiently resilient to withstand the thermal and chemical conditions employed in the curing and carbonization processes. For many applications, the substrate can be selected from, for example, a metal (e.g., Co, Ni, Cu, Zn, Ti, Pt, Au, Ru, Mo, W, Ta, or Rh, stainless steel, a metal alloy, or combination thereof), a metal oxide (e.g., glass or a ceramic material), a metal nitride (e.g., TaN), a metal carbide, a metal silicide, a metal boride, or a combination thereof, or multilayer composite thereof. Moreover, the resulting deposited metal-carbon composite may be overlaid by a layer of the same or different material to produce a multilayer structure. The overlaid structure can be composed of, for example, any of the substrates described above, or composed of a heat-sensitive organic material, such as a protective polymeric film.

In some embodiments, the substrate has a substantially flat (i.e., planar) surface in the substantial absence of structural features. In other embodiments, the substrate surface contains surface structural features that either protrude and/or recede into the surface. In particular embodiments, the substrate surface contains a collection or array of structural features, in which case the substrate surface can be regarded as having a high feature density. In some embodiments, the structural features may be present throughout the substrate surface. The structural features may be of nanoscale, microscale, or macroscale dimension. Some examples of protruding features include raised lines, bumps, and pillars. Some examples of recessive features include recessive lines, trenches, and pores. In some embodiments, the substrate is non-porous, while in other embodiments the substrate is porous. In the case of a porous substrate, the porosity may be attributed to micropores, mesopores, or macropores. Methods for producing features on a substrate are well known, and can include, for example, etching (e.g., anodic etching), lithographical patterning, chemical treatment, and chemical or physical vapor deposition. In some embodiments, the features are uniformly distributed.

The film of precursor composition, as originally applied to the substrate, can have any suitable thickness. The film can have a thickness of precisely, about, up to, less than, at least, or above, for example, 100 μm, 50 μM, 25 μm, 10 μm, 5 μm, 2 μm, 1 μm, 500 nm, 400 nm, 300 nm, 200 nm, 100 nm, 75 nm, 50 nm, 25 nm, 20 nm, 15 nm, 10 nm, 5 nm, 4 nm, 3 nm, 2 nm, or 1 nm, or a thickness within a range bounded by any two of the foregoing values. Any of the foregoing thicknesses may alternatively and independently be the thickness of the cured precursor film or resulting carbonized film.

In other embodiments, a monolithic version of the metal-carbon composite is produced. As used herein, the term “monolithic” means that the metal-carbon composite is not bonded to or in contact with a substrate. A monolithic version of the metal-carbon composite can be achieved by, for example, first producing a coating of the metal-carbon composite on a substrate, as described above, followed by separating the metal-carbon composite from the substrate. The layer of metal-carbon composite can be separated from the substrate by, for example, mechanical means, such as pulling, peeling, or scraping of the metal-carbon composite coating from the substrate. In the mechanical separation process, the shape of the metal-carbon composite, which adopts the shape of the substrate, may be substantially preserved; alternatively, the mechanical process destroys the shape of the metal-carbon composite on the substrate, wherein the latter case may be useful where a particulate version of the metal-carbon composite is desired. A grinding process may additionally be employed to further diminish the size of pieces of composite produced from the mechanical separation process. In other embodiments, the layer of metal-carbon composite is separated from the substrate by chemical or physical destruction of the substrate. In such cases, the substrate is selected to function as a sacrificial substrate. For example, the substrate may undergo chemical dissolution by treatment with a chemical of sufficient reactivity, e.g., the action of hydrofluoric acid on a silicon oxide substrate, wet acid etching of a zinc oxide substrate, or wet alkaline etching of a silicon substrate (e.g., with KOH or tetramethylammonium hydroxide). Alternatively, the substrate is a heat-sensitive material (e.g., a polymer) that thermally decomposes during the curing and/or carbonization process.

A monolithic version of the metal-carbon composite can be alternatively achieved by molding the precursor composition into a desired shape. Some possible shapes include, for example, sheets, rods, tubes, and fibers, depending on the application. For example, the precursor solution may be poured into a mold of desired shape, and the mold with precursor treated by curing and carbonization, followed by release of the metal-carbon composite from the mold. The invention may employ any of the molding and mold release methods well known in the art. Other molding and shaping methods, such as pressing, stamping, indenting, cutting, and sheet rolling may also be used. In some embodiments, the precursor composition is cured or semi-cured into a highly viscous gel or semi-solid before being shaped, followed by optional additional curing and then carbonization.

In some embodiments, the precursor composition can be treated in such a manner as to directly form particles of the metal-carbon composite described above. The particles can be produced by any suitable method, such as, for example, spray atomization techniques known in the art capable of heating at carbonization temperatures. For example, the precursor composition described above (typically, in a carrier solvent, such as THF or DMF) can be sprayed through the nozzle of an atomizer, and the particulates directed into one or more heated chambers for curing and carbonization steps. In different embodiments, the particles can be about, at least, above, up to, or less than, for example, 50 nm, 100 nm, 200 nm, 500 nm, 1 μm, 2 μm, 5 μm, 10 μm, 50 μm, 100 μm, 500 μm, or 1000 μm, or within a range bounded by any two of these values.

In some embodiments, a multi-step process is employed by including one or more deposition steps before the curing and/or carbonization steps. For example, a multi-step process may be employed wherein a film of the phenolic compound or material, with or without admixture with the metal-containing particles, is first produced by, for example, coating the aforesaid mixture of components onto a surface. The produced film may then subsequently be reacted with the crosslinkable aldehyde component (e.g., by a vapor phase reaction with, for example, formaldehyde vapor) in the presence of the catalyst to produce the polymerized (and optionally, crosslinked) carbon precursor material. The resulting cured film can then be carbonized to produce the metal-carbon composite. In some embodiments, a precursor film not containing the metal-containing particles (e.g., containing at least the phenolic, aldehyde, porogen, and catalyst components, and optionally, carbon particles) is applied to a substrate surface, and the precursor film subjected to curing and carbonization steps to form a porous carbonized version of the precursor film. The porous carbonized version of the precursor film, which may or may not include carbon particles, is then contacted with the metal-containing particles (e.g., by a liquid impregnation method, as well known in the art) in order to incorporate the metal-containing particles into at least the surface of the carbonized precursor film. In some embodiments, a single-step deposition process is used in which all components of the precursor solution are included in a single precursor solution, and the single precursor solution deposited on a substrate before being cured and carbonized.

The method for forming a metal-carbon composite, described above, can also be useful in storing and/or treating nuclear fuel (e.g., UO₂) and nuclear fuel waste. In particular, uranium oxide, plutonium oxide, or thorium oxide particles can be incorporated into the precursor composition, and the mixture carbonized in order to entrap the particles. The carbonized mixture may also be heated to sufficient temperature to induce the entrapped particles to form the corresponding metal carbide composition.

The metal-carbon composite can also be functionalized, if desired, by methods known in the art for functionalizing carbon or graphite materials. For example, the metal-carbon composite may be nitrogenated, fluorinated, or oxygenated by methods known in the art by, for example, exposure of the composite, either during or after the carbonization process, to, respectively, ammonia, fluorine gas, or oxygen under suitably reactive conditions. In the particular case of fluorination, the composite is typically placed in contact with fluorine gas for a period of several minutes (e.g., 10 minutes) up to several days at a temperature within 20° C. to 500° C., wherein the time and temperature, among other factors, are selected based on the degree of fluorination desired.

The metal-carbon composite may also be impregnated with one or more species that become incorporated into or bind with any part of the metal-carbon composite. For example, particularly for the purpose of applying the metal-carbon composite as a negative electrode in a lithium ion battery, lithium ions may be incorporated. The positive electrode in a lithium ion battery is typically an oxide, such as lithium cobalt oxide, lithium iron phosphate, or a spinel, such as manganese oxide. If applied to a primary lithium battery, the anode typically employs lithium metal or a lithium compound.

In another aspect, the invention is directed to an electrode-containing device that includes the metal-carbon composite, described above, on or in at least one of the electrodes of the device. The electrode-containing device into which the composite is incorporated can be, for example, a capacitive deionization (CDI) device, battery (e.g., a lithium or lithium ion battery), capacitor, supercapacitor, or electric double layer capacitor (EDLC). When incorporated into the device, the metal-carbon composite may be disposed as a layer on a suitable substrate (e.g., a titanium substrate) or may be incorporated in monolithic form (i.e., not on a substrate) as an electrode. Whether the composite is on a substrate or in monolithic form, the metal-carbon composite may, in some embodiments, be admixed in powder form with a binder, such as PVDF, and pressed or molded to produce the final electrode material. In some embodiments, to improve the conductivity, conductive carbon particles are also included along with the binder to produce the final electrode material.

The invention is also directed to a method for desalinating water by electrically operating a CDI device in which the metal-carbon composite is incorporated. A CDI device generally includes at least the feature of two porous electrodes of opposite polarity spaced in such a manner that flowing liquid (typically water, or an aqueous solution containing water) makes contact with the electrodes. In some embodiments, the electrodes are separated by an insulating material that permits the flow therethrough of water to be deionized by inclusion of flow channels in the insulating material. The insulating material includes means (e.g., spaces, channels, or pores) that permit the liquid to make efficient contact with the porous electrodes. When operated (i.e., by applying a suitable voltage bias across the electrodes), the CDI device removes salt species from the water by absorbing cationic species into the negatively charged electrode and anionic species into the positively charged electrode, similar to a capacitor, such as a supercapacitor or EDLC, both of which are additional applications for the metal-carbon composite described herein. The base electrode material can be any suitable electrically conductive material, including any of the substrate materials described above, provided the substrate material permits the CDI device to desalinate water. In particular embodiments, the base electrode material is porous.

The CDI device can have any of the features and designs known in the art. Reference is made, for example, to U.S. Pat. No. 5,636,437, U.S. Pat. No. 5,776,633, U.S. Pat. No. 5,932,185, U.S. Pat. No. 5,954,937, U.S. Pat. No. 6,214,204, U.S. Pat. No. 6,309,532, U.S. Pat. No. 6,778,378, U.S. Pat. No. 7,766,981, U.S. Pat. No. 7,835,137, U.S. Application Pub. No. 2008/0274407, U.S. Application Pub. No. 2009/0141422, U.S. Application Pub. No. 2009/0305138, U.S. Application Pub. No. 2009/0320253, H.-H. Jung, et al., Desalination, 216, pp. 377-385 (2007), R. W. Pekala, et al., Journal of Non-Crystalline Solids, 225, pp. 74-80 (1998), and D. Carriazo, et al., J Mater. Chem., 20, pp. 773-780 (2010), all of which describe numerous features and designs in CDI, EDLC, and related devices, as well as numerous methods for fabricating electrodes in such devices, as well as methods of operating CDI, EDLC and related devices. The variations and designs of CDI devices, as well as methods of manufacture, and methods of their use, described in the foregoing references, are herein incorporated by reference in their entirety. In some embodiments, one or more features described in said references are excluded from the instant CDI device. Moreover, in some embodiments, two electrodes are employed, while in other embodiments, more than two, or a multiplicity of electrodes (for example, miniaturized electrodes) are employed. In some embodiments, the electrodes are in a stacked arrangement, such as an alternating left-right arrangement to maximize flow rate. In particular embodiments, the CDI device is a membrane capacitive deionization (MCDI) device by employing an anion-exchange membrane coated on the anode and/or a cation-exchange membrane coated on the cathode, wherein the anion- or cation-exchange membrane is generally positioned between the flowing water and respective electrode. In other embodiments, such exchange membranes are excluded from the device.

The invention is also directed to a method of energy storage or conversion by operating an energy storage or conversion device in which the metal-carbon composite is incorporated. The energy storage or conversion device can be, for example, a lithium battery, lithium ion battery, capacitor, supercapacitor, electric double layer capacitor, or photovoltaic device. The operation of such devices is well known in the art.

While there have been shown and described what are at present considered the preferred embodiments of the invention, those skilled in the art may make various changes and modifications which remain within the scope of the invention defined by the appended claims.

What is claimed is:

1. A method of forming a metal-carbon composite, the method comprising subjecting a precursor composition to a curing step followed by a carbonization step, the precursor composition comprising: (i) a phenolic component, (ii) a crosslinkable aldehyde component, (iii) a polymerization catalyst, and (iv) metal-containing particles, wherein said carbonization step comprises heating the precursor composition at a carbonizing temperature of at least 300° C. for sufficient time to convert the precursor composition to said metal-carbon composite.

2. The method of claim 1, wherein said metal is an element selected from Groups 3-14, lanthanide, and actinide metals of the Periodic Table.

3. The method of claim 1, wherein said metal is a transition metal selected from Groups 3-12 of the Periodic Table.

4. The method of claim 1, wherein said metal is in a zerovalent state and in an elemental or alloy form.

5. The method of claim 1, wherein said metal is in a non-zerovalent state and in the form of a compound that contains at least one element of opposite charge.

6. The method of claim 1, wherein said precursor composition is deposited as a liquid coating onto a solid substrate, followed by curing and carbonization of the liquid coating to produce a metal-carbon composite coating on said solid substrate.

7. The method of claim 6, wherein said solid substrate contains surface structural features that protrude from or recede into the surface.

8. The method of claim 7, wherein said solid substrate is porous.

9. The method of claim 6, wherein said metal-carbon composite is separated from said solid substrate to produce a monolithic metal-carbon composite that retains the shape of the solid substrate.

10. The method of claim 1, wherein said precursor composition is poured into a mold followed by curing, carbonization, and mold release to form a monolithic metal-carbon composite.

11. The method of claim 1, wherein said metal-carbon composite is non-porous.

12. The method of claim 1, wherein said metal-carbon composite is porous.

13. The method of claim 12, wherein said metal-carbon composite is mesoporous.

14. The method of claim 1, wherein said precursor composition further comprises a porogen.

15. The method of claim 1, wherein said precursor composition further comprises a templating component.

16. The method of claim 15, wherein said templating component comprises a block copolymer.

17. The method of claim 16, wherein said block copolymer is a poloxamer copolymer.

18. The method of claim 1, wherein said phenolic compound is selected from the group consisting of phenol, catechol, resorcinol, dihydroquinone, phloroglucinol, cresols, halophenols, aminophenols, hydroxybenzoic acids, dihydroxybiphenyls, and phenol-containing macromolecules.

19. The method of claim 1, wherein said precursor composition further comprises carbon particles.

20. The method of claim 1, wherein said precursor composition is a liquid solution that further comprises an organic solvent.
